(19) United States
(12) Patent Application Publication
(10) Pub. No.: US 2026/0353623 A1
(43) Pub. Date: Nov. 5, 2026

(54) METHOD AND SYSTEM FOR SEPARATING AN ASSEMBLY

(71) Applicants: Endress+Hauser SE+Co. KG, Maulburg (DE); REHM THERMAL SYSTEMS GMBH, Blaubeuren, Deutschland (DE)

(72) Inventors: Dietmar Birgel, Schopfheim (DE); Alexander Bannwarth, Schwörstadt (DE); Joachim Erhard, Berghülen (DE); Paul Wild, Heroldstatt (DE)

(21) Appl. No.: 19/486,745

(22) PCT Filed: Apr. 2, 2024
(86) PCT No.: PCT/EP2024/058943

§ 371 Date: Nov. 21, 2025

(30) Foreign Application Priority Data
May 31, 2023 (DE) 10 2023 114 319.0

(51) Int. Cl. H05K 13/04; H05K 3/22; H05K 13/00

(52) U.S. Cl. CPC H05K 13/0486; H05K 3/225; H05K 13/0061; H05K 2203/111; H05K 2203/1121; H05K 2203/176

(57) ABSTRACT

A method for separating an assembly, wherein the assembly includes at least one component and a circuit board, wherein the at least one component is connected to the circuit board by a one solder connection, comprises performing a thermal conditioning of the at least one solder connection by heating the at least one solder connection, and after the step of heating, cooling the at least one solder connection with a cooling rate such that the at least one solder connection is solid, wherein the cooling rate is greater than 6 °C/s; and separating the at least one component from the circuit board by means of action of a force, such that a brittle fracture of the at least one solder connection occurs. Further disclosed is a system for separating an assembly.

The invention relates to a method for separating an assembly, wherein the assembly includes at least one component and a circuit board, wherein the at least one component is connected to the circuit board by means of at least one solder connection. The invention relates further to a system for separating an assembly.

A solder connection is obtained by a solder joining method, which produces a material bonded connection by means of a thermal method.

Circuit boards with components soldered thereon are applied in the field devices of automation technology manufactured and sold by the Endress+Hauser group of companies. Field devices are applied for determining and/or monitoring process variables. Referred to as field devices, in such case, are, in principle, all devices, which are applied near to a process and which deliver, or process, process relevant information. Involved, for example, are fill level measuring devices, flowmeters, pressure-and temperature measuring devices, pH-redox potential measuring devices, conductivity measuring devices, etc., which register the corresponding process variables, fill level, flow, pressure, temperature, pH value, and conductivity. Field devices have often, especially at least at times and/or at least sectionally contacting a process medium, a sensor unit, which serves to produce a signal dependent on the process variable. Furthermore, they often include, arranged in a housing, an electronics, wherein the electronics serves for the processing and/or forwarding of signals, especially electrical and/or electronic signals, produced by the sensor unit.

Electronic units often comprise at least one circuit board with components soldered thereon using one or more soldering methods. Different soldering methods are known from the state of the art and their use is determined especially by the components to be soldered and/or by the solder.

A soldering method widely used in industrial production lines for producing the circuit boards is reflow soldering, in the case of which surface-mountable components, so called ‘Surface Mounted Devices’ (short: SMD components), are directly soldered to contact areas provided for them. For this, the SMD components are placed by machine on solder paste equipped contact areas on the circuit board using automatic populating machines and soldered using a reflow soldering process in a reflow soldering oven. In this way, a large number of solder connections are produced simultaneously.

Besides the SMD components, there are certain components, which because of their function have greater dimensions. These components are preferably formed as through hole technology components—short: THT components. THT components are typically soldered in a wave soldering process. In such case, the circuit board is moved over a so-called solder wave, which is produced by pumping liquid solder through a narrow gap.

Common to both reflow soldering as well as also wave soldering, in such case, is that the solder and the product to be soldered are exposed to a temperature profile during the soldering process. Thus, there is a temperature time curve associated with the soldering. The temperature profile typically includes a preheating of the solder and/or the product to be soldered, the reaching of a maximum temperature, which lies above the liquidus temperature of the solder, and a following cooling. In the state of the art, one tries to achieve small cooling rates, in order that the solder connections are of sufficiently high quality, i.e., for example, in order to produce a high strength solder connection with sufficiently great mechanical durability.

Such solder connections have, however, the disadvantage that, for removing the component from the contact area, the one or more solder connections of the component have to be melted again. Such is, on the one hand, energy intensive, and, on the other hand, in such case, poisonous vapors can arise. For protecting the environment and for an improved possibility for recycling, circuit boards, it is desirable to provide a simpler possibility for removing the components. This is true especially for circuit boards, which are applied in devices with comparatively short lifetime, such as, for example, 2 to 10 years.

An object of the invention is to provide a method and a system for separating a component from a circuit board.

The object is achieved according to the invention by a method as defined in claim 1 as well as a system as defined in claim 6.

As regards the method, the object is achieved according to the invention by a method for separating an assembly, wherein the assembly includes at least one component and a circuit board, wherein the at least one component is connected to the circuit board by means of at least one solder connection, wherein the method comprises steps as follows:
performing a thermal conditioning of the at least one solder connection, comprising steps as follows:
   heating the at least one solder connection,
   after the step of heating, cooling the at least one solder connection with a cooling rate such that the at least one solder connection is solid, wherein the cooling rate is greater than 6 °C/s,
separating the at least one component from the circuit board by means of action of a force, such that a brittle fracture of the at least one solder connection occurs.

According to the invention, an already present solder connection of an assembly is thermally conditioned in such a manner that it becomes brittle fracturing. In such case, the thermal conditioning, i.e. the heating and fast cooling of the solder connection leads to a change of the mechanical properties, especially the plastic properties, of the at least one solder connection. As a rule, soldering methods are so embodied that a stable solder connection is obtained via a longer period of time. The solder connection produced during soldering methods is therewith typically non-brittle, thus ductile, wherein non-brittle and ductile in the sense of this invention mean that the solder connection is not separable by a brittle fracture. Brittle fracture refers in fracture mechanics to an abruptly occurring material failure. Brittle fracturing materials, and solder connections, are characterized in the stress-strain graph by a steep rise of the Hooke's Law line, at whose end the fracture occurs without plastic deformation.

In order to produce a solder connection separable by a brittle fracture, the already present solder connection can be subsequently thermally conditioned. The heating of the at least one solder connection can lead to an exceeding of a liquidus temperature of the at least one solder connection. However, this is not a requirement, but, instead, the heating can also be a heating of the at least one solder connection to temperatures below a liquidus temperature of the at least one solder connection, especially, for example, at least 20 °C, especially at least 40 °C, below the liquidus temperature of the at least one solder connection. Decisive in a conditioning is the rapid cooling of the at least one solder connection at a cooling rate of at least 6 °C/s. At this cooling rate, the properties of the at least one solder connection change in such a manner that a brittle fracturing solder connection is produced. Such is then, under action of a force, brittle fractured, such that the at least one component is separated from the circuit board. The method step of separating the at least one component from the circuit board can especially be performed at room temperature.

With the help of the thermal conditioning of the at least one solder connection, it is, thus, achieved that the at least one component can be separated from the circuit board in simple manner.

In a case, in which the at least one component has a plurality of solder connections or the circuit board is connected with a plurality of components, a good portion of the components can advantageously be separated by means of brittle fracture from the circuit board essentially at the same time under action of force on the solder connections.

Especially used as cooling rate is a cooling rate of greater than 8 °C/s, especially greater than 10 °C/s. The cooling rate can be less than 50°/s.

In an embodiment, the cooling rate is set by means of supplying a liquid medium to the at least one solder connection. The liquid medium can especially be liquid nitrogen, however, also other liquid media are possible, such as, for example, water or oil or media containing water or oil. The liquid medium serves especially as cooling means.

Applied in an additional embodiment for separating the at least one component from the circuit board is a force action of less than 40 N, especially less than 30 N, especially less than 20 N, especially less than 10 N.

Preferably, the at least one component of the circuit board is separated by means of twisting, negative pressure, ultrasound, dry ice, air knife, free fall, a shock-like mechanical loading and/or a brush. Referred to as twisting is especially a deformation or bending of the circuit board. Referred to as air knife is a nozzle, from which an air stream escapes with high velocity. As regards the free fall, a fall apparatus can be used, in which the assembly is mounted and allowed to fall under action of the acceleration of gravity over a defined distance, until the assembly impinges on a strike surface. The at least one component can be sheared from the circuit board by means of the brush.

As regards the system, the underpinning object of the present invention is further achieved by a system for separating an assembly, wherein the assembly includes at least one component and a circuit board, wherein the at least one component is connected to the circuit board by means of at least one solder connection, comprising
a heating region, which is embodied to heat the at least one solder connection,
a cooling region, which is embodied to cool the at least one solder connection after the heating region to assure that the at least one solder connection is solid, wherein the cooling rate is greater than 6 °C/s, and
a separating region, which is embodied to separate the at least one component from the circuit board by means of action of a force, such that a brittle fracture of the at least one solder connection occurs.

In the system of the invention, an assembly is thermally conditioned and then by means of brittle fracture separated into its parts, i.e. circuit board and one or more components. In such case, the system is embodied in such a manner that the assembly passes, firstly, the heating region, then the cooling region and, finally, the separating region. The system of the invention is especially suitable for performing the method of the invention.

In an embodiment, the heating region includes at least one heating element.

In an additional embodiment, the cooling region includes at least one heat exchanger.

In a further development, the cooling region includes an opening, by means of which a liquid medium is suppliable in the cooling region. The liquid medium can be especially liquid nitrogen. However, also other liquid media are possible, such as, for example, water or oil, or media containing water or oil.

Preferably, the system further includes a transport means for receiving the circuit board, wherein the transport means is embodied to transport the assembly through the heating region, the cooling region and the separating region. The transport means can be embodied in the form of a conveyor belt. The conveyor belt can be embodied as a single piece or in the form of a plurality of modular sections.

Especially, the transport means can be embodied to transport the circuit board and the at least one component in the separating region separately after the separating of the at least one component from the circuit board. For example, the transport means can have two regions, of which one is embodied for transporting the circuit board and the other for transporting the at least one component.

Another embodiment provides that the separating region includes a separating means, which is embodied to exert the force on the at least one solder connection.

Especially, the separating means is a brush, an air knife, an ultrasonic device, a fall apparatus, a means for producing a negative pressure and/or a means for twisting the circuit board.

The invention will now be explained in greater detail based on the appended drawing, the figures of which show as follows:

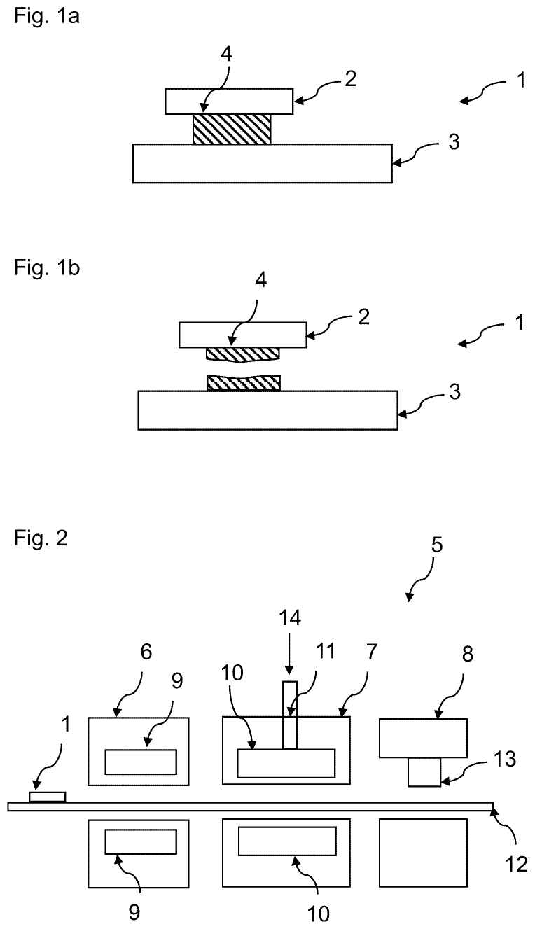

FIGS. 1a-b schematic view of the assembly before and after separating the at least one component of the circuit board; and

FIG. 2 an embodiment of a system of the invention.

The method of the invention and the system of the invention are usable on assemblies comprising at least one component and a circuit board, which are connected by means of at least one solder connection.

An assembly 1 is produced by a solder joining method, for example, a reflow soldering. In such case, a solder, for example, in the form of a solder paste, is deposited on a contact area of the at least one component 2 or the circuit board 3. Then, the at least one component 2 is placed on the circuit board 3 and soldered to the circuit board 3 in a thermal process. Such an assembly 1 is shown schematically in FIG. 1a. The assembly 1 can be used after its production in a wide variety of electrical or electronic devices, such as, for example, field devices, measuring devices, laboratory devices or consumer devices. After the passing of the life cycle of the device, such is, as a rule, disposed of. In order to recycle the assembly 1, it needs to be removed from the device and separated into its individual parts, for which purpose the at least one solder connection 4 must be removed.

The method of the invention provides that the at least one solder connection 4 of the assembly 1 is thermally conditioned, in that such is, firstly, heated and then cooled at a cooling rate of at least 6 °C/s. Due to the high cooling rate, the mechanical properties of the at least one solder connection 4 change, such that brittle fracturing properties result. After the thermal conditioning, the at least one component 2 is separated from the circuit board 3 under action of a force F, such that a brittle fracture occurs at the at least one solder connection 4. Applied in this separating step is especially a force F of less than 40 N, especially less than 30 N, especially less than 20 N, especially less than 10 N. FIG. 1b shows a schematic view of the assembly 1 after the separating step. The solder connection 4 is brittle fractured and the at least one component 2 and the circuit board 3 are separated.

FIG. 2 shows an embodiment of the system 5 of the invention, where the method of the invention can be applied. System 5 includes three regions: a heating region 6 for heating the at least one solder connection 4, a cooling region 7 for cooling of the at least one solder connection 4 and a separating region 8 for separating the at least one component 2 from the circuit board 3. Assembly 1 is set on an optional transport means 12, which is embodied to transport the assembly 1 through the heating region 6, the cooling region 7 and the separating region 8. Assembly 1 passes, firstly, the heating region 6, which has optionally two heating elements 9 for heating the at least one solder connection 4.

Finally, the assembly 1 is transported into the cooling region 7, which has two optional heat exchangers 10. Heat exchangers 10 are embodied to cool the at least one solder connection 4 with the cooling rate of at least 6 °C/s. Cooling region 7 can further include an opening 11, by means of which a liquid medium is suppliable into the cooling region 7. The liquid medium is embodied to support the cooling process.

After the at least one solder connection 4 is cooled off and thermally conditioned in the cooling region 7, the assembly 1 is brought into the separating region 8. There, for example, a separating means 13 is arranged, which is embodied to exert a force F on the at least one solder connection 4, such that the at least one solder connection 4 undergoes brittle fracture and the at least one component 2 is separated from the circuit board 3. Separating means 13 can be a brush, which is embodied to shear the at least one component 2 from the circuit board 3. Separating means 13 can be alternatively or supplementally an air knife for producing an air stream of high velocity, an ultrasonic device for producing ultrasonic waves, a means for producing a negative pressure, such as, for example, a pump, a fall apparatus for the defined letting fall of the assembly and hitting of the assembly on a strike surface and/or a means for twisting the assembly.

### LIST OF REFERENCE CHARACTERS

1 assembly
2 component
3 circuit board
4 solder connection
5 system
6 heating region
7 cooling region
8 separating region
9 heating element
10 heat exchanger
11 opening
12 transport means
13 separating means
F force

1-13. (canceled)

14. A method for separating an assembly, wherein the assembly includes at least one component and a circuit board, wherein the at least one component is connected to the circuit board by at least one solder connection, the method comprising:
performing a thermal conditioning of the at least one solder connection, including:
heating the at least one solder connection; and
after the step of heating, cooling the at least one solder connection with a cooling rate such that the at least one solder connection is solid, wherein the cooling rate is greater than 6 °C/s; and
separating the at least one component from the circuit board by an action of a force such that a brittle fracture of the at least one solder connection occurs.

15. The method as claimed in claim 14,
wherein a cooling rate of greater than 8 °C/s is used as the cooling rate.

16. The method as claimed in claim 15,
wherein the cooling rate is set by supplying a liquid medium to the at least one solder connection.

17. The method as claimed in claim 14,
wherein the force of less than 40 N is applied for separating the at least one component from the circuit board.

18. The method as claimed in claim 14,
wherein the at least one component is separated from the circuit board by twisting, negative pressure, ultrasound, dry ice, air knife, free fall, shock-like mechanical loading, and/or a brush.

19. A system for separating an assembly, wherein the assembly includes at least one component and a circuit board, wherein the at least one component is connected to the circuit board by at least one solder connection, the system comprising:
a heating region that is embodied to heat the at least one solder connection;
a cooling region that is embodied to cool the at least one solder connection after the heating region to assure that the at least one solder connection is solid, wherein the cooling rate is greater than 6 °C/s; and
a separating region that is embodied to separate the at least one component from the circuit board by of an action of a force such that a brittle fracture of the at least one solder connection occurs.

20. The system as claimed in claim 19,
wherein the heating region includes at least one heating element.

21. The system as claimed in claim 19,
wherein the cooling region includes at least one heat exchanger.

22. The system as claimed in claim 21,
wherein the cooling region includes an opening by which a liquid medium is suppliable in the cooling region.

23. The system as claimed in claim 19, further comprising:
a transport means for receiving the circuit board, wherein the transport means is embodied to transport the assembly through the heating region, the cooling region, and the separating region.

24. The system as claimed in claim 23,
wherein the transport means is embodied to transport the circuit board and the at least one component in the separating region separately after the separating of the at least one component from the circuit board.

25. The system as claimed in one of claim 19,
wherein the separating region includes a separating means that is embodied to exert the force on the at least one solder connection.

26. The system as claimed in claim 25,
wherein the separating means is a brush, an air knife, an ultrasonic device, a fall apparatus, a means for producing a negative pressure, and/or a means for twisting the circuit board.
